(19) United States
(12) Patent Application Publication
(10) Pub. No.: US 2024/0055431 A1
(43) Pub. Date: Feb. 15, 2024

(54) MULTI-THRESHOLD INTEGRATED CIRCUIT AND METHOD OF DESIGNING THE SAME

(71) Applicant: SAMSUNG ELECTRONICS CO., LTD., Suwon-Si (KR)

(72) Inventors: Minjae JEONG, Suwon-si (KR); Jisu YU, Suwon-si (KR); Geonwoo NAM, Suwon-si (KR); Jungho DO, Suwon-si (KR); Hyeongyu YOU, Suwon-si (KR); Jaehee CHO, Suwon-so (KR)

(73) Assignee: SAMSUNG ELECTRONICS CO., LTD., Suwon-si (KR)

(21) Appl. No.: 18/222,734

(22) Filed: Jul. 17, 2023

(30) Foreign Application Priority Data
Aug. 9, 2022 (KR) 10-2022-0099507

(51) Int. Cl. H01L 27/092; H01L 23/528; G06F 30/392

(52) U.S. Cl. CPC H01L 27/0922; H01L 23/528; G06F 30/392

(57) ABSTRACT

An integrated circuit includes a first cell disposed in a first row and a second row, which are adjacent to each other and extend in a first direction, and including a plurality of first threshold voltage devices and at least one second cell disposed adjacent to the first cell in at least one of the first row and the second row and including at least one second threshold voltage device, wherein the plurality of first threshold voltage devices include at least one first device configured to perform a first function in the first row and at least one second device configured to perform a second function, which is different from the first function, in the second row.

### CROSS-REFERENCE TO RELATED APPLICATION

This application is based on and claims priority to Korean Patent Application No. 10-2022-0099507, filed on Aug. 9, 2022, in the Korean Intellectual Property Office, the disclosure of which is incorporated by reference herein in its entirety.

### BACKGROUND

The disclosure relates to an integrated circuit, and more particularly, to an integrated circuit including devices having different threshold voltages and a method of designing the integrated circuit.

To satisfy various needs, an integrated circuit may include a plurality of devices respectively having different characteristics. For example, an integrated circuit may include devices respectively having different threshold. A device having a lower threshold voltage may have a high operation speed and high power consumption, and a device having a higher threshold voltage may have a low operation speed and low power consumption. As semiconductor device manufacturing processes advance, devices may have a reduced size, and it may not be easy to integrate devices having different threshold voltages into an integrated circuit.

### SUMMARY

Embodiments of the disclosure provide an integrated circuit including multi-threshold devices and a method of designing the integrated circuit.

According to an embodiment, there is provided an integrated circuit including a first cell disposed in a first row and a second row, which are adjacent to each other and extend in a first direction, and including a plurality of first threshold voltage devices and at least one second cell disposed adjacent to the first cell in at least one of the first row and the second row and including at least one second threshold voltage device, wherein the plurality of first threshold voltage devices include at least one first device configured to perform a first function in the first row and at least one second device configured to perform a second function, which is independent of the first function, in the second row.

According to an embodiment, there is provided an integrated circuit including a first cell disposed in a first row extending in a first direction and including a plurality of first threshold voltage devices, a second cell disposed in a second row, which is adjacent to the first row and extends in the first direction, and including a plurality of first threshold voltage devices, and at least one third cell disposed adjacent to the first cell and the second cell in the first row and the second row, the at least one third cell including at least one second threshold voltage device, wherein the first cell and the second cell are aligned in a second direction perpendicular to the first direction and have the same length in the first direction.

According to an embodiment, there is provided a method of designing an integrated circuit including a plurality of cells, the method including obtaining a netlist defining the plurality of cells and placing the plurality of cells in a plurality of rows extending in a first direction, based on the netlist, wherein the placing of the plurality of cells includes placing at least one first cell including a first threshold voltage device and at least one second cell including a second threshold voltage device to abut each other at a boundary extending in a second direction perpendicular to the first direction.

### BRIEF DESCRIPTION OF DRAWINGS

Embodiments will be more clearly understood from the following detailed description taken in conjunction with the accompanying drawings in which:

FIG. 1 is a diagram illustrating a standard cell according to an embodiment;

FIG. 2 is a graph showing a relationship between power and performance of a device, according to an embodiment;

FIGS. 3A to 3D are diagrams illustrating examples of a device according to embodiments;

FIG. 4 is a diagram illustrating a layout of an integrated circuit according to an embodiment;

FIGS. 5A and 5B are diagrams illustrating examples of a layout of an integrated circuit according to embodiments;

FIGS. 6A and 6B are diagrams illustrating examples of a layout of an integrated circuit according to embodiments;

FIG. 7 is a flowchart illustrating a method of designing an integrated circuit, according to an embodiment;

FIG. 8 is a flowchart illustrating a method of designing an integrated circuit, according to an embodiment;

FIG. 9 is a flowchart illustrating a method of designing an integrated circuit, according to an embodiment;

FIG. 10 is a flowchart illustrating a method of designing an integrated circuit, according to an embodiment;

FIG. 11 is a block diagram illustrating a system on chip according to an embodiment; and

FIG. 12 is a block diagram illustrating a computing system including a memory storing a program, according to an embodiment.

### DETAILED DESCRIPTION

The embodiments described herein are example embodiments, and thus, the disclosure is not limited thereto and may be realized in various other forms. As used herein, expressions such as “at least one of” when preceding a list of elements, modify the entire list of elements and do not modify the individual elements of the list. For example, the expression, “at least one of a, b, and c” should be understood as including only a, only b, only c, both a and b, both a and c, both b and c, or all of a, b, and c.

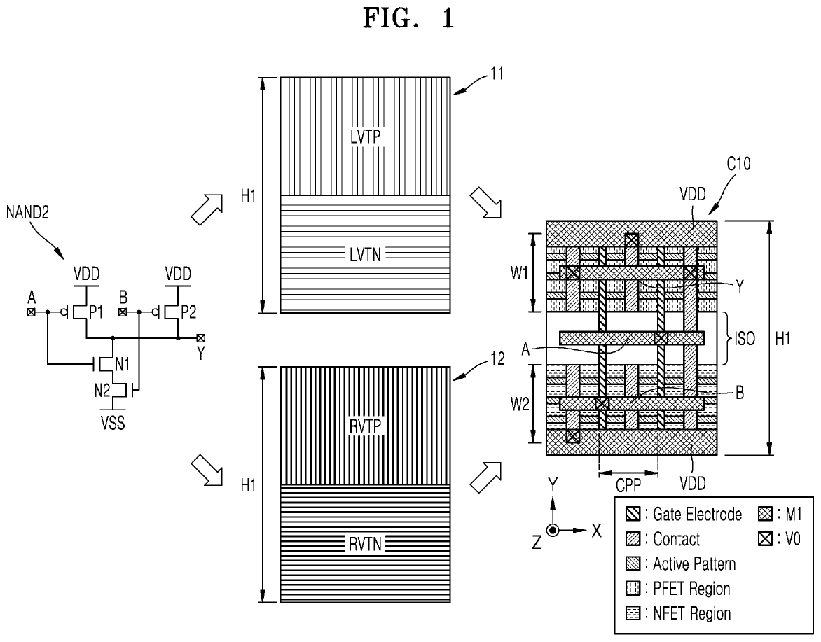

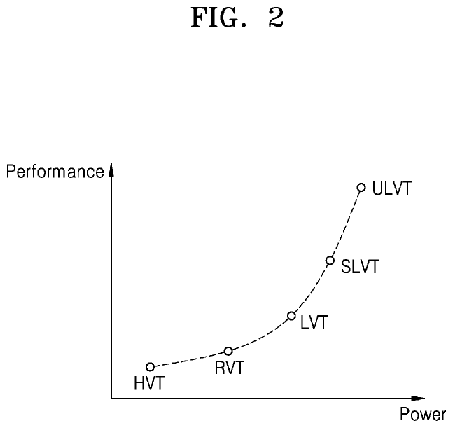

FIG. 1 is a diagram illustrating a standard cell according to an embodiment, and FIG. 2 is a graph showing a relationship between power and performance of a device, according to an embodiment.

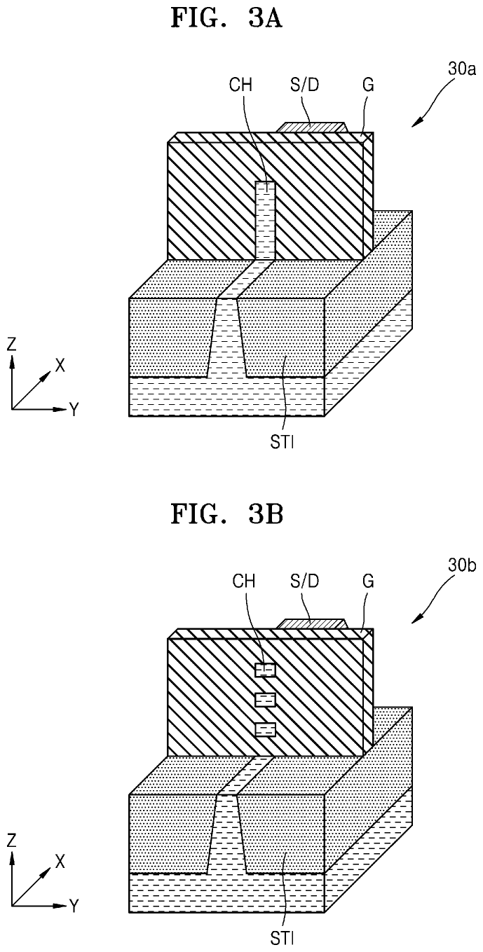

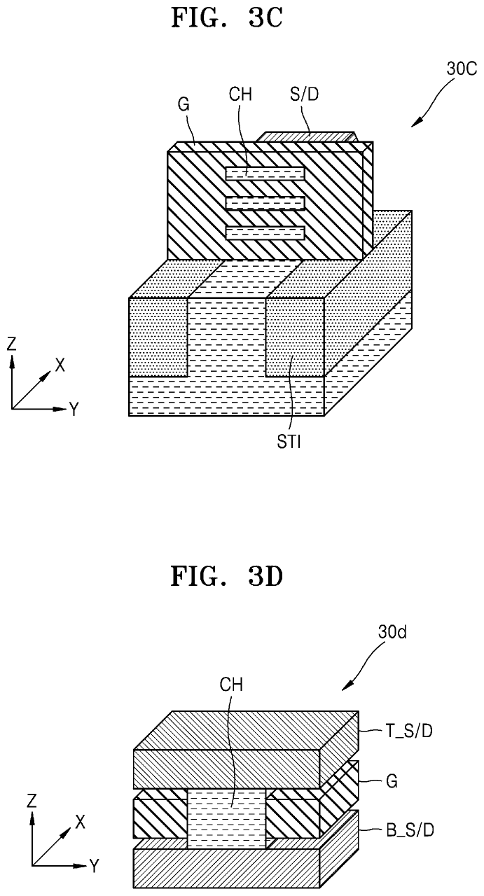

Referring to FIG. 1, a 2-input NAND gate NAND2 may be implemented as a cell C10 in an integrated circuit. The 2-input NAND gate NAND2 may have two inputs A and B and an output Y and may include devices such as first and second n-type field-effect transistors (NFETs) N1 and N2 and first and second p-type field-effect transistors (PFETs) P1 and P2. FIG. 1 illustrates the cell C10 including a plurality of fin field-effect transistors (FinFETs) configured by active patterns extending in an X-axis direction and a gate electrode extending in a Y-axis direction, but as described below with reference to FIGS. 3A to 3D, a cell may include devices having various different structures.

Herein, the X-axis direction and the Y-axis direction may be respectively referred to as a first direction and a second direction, and a Z-axis direction may be referred to as a vertical direction or a third direction. A plane consisting of an X axis and a Y axis may be referred to as a horizontal plane, an element disposed in a +Z-axis direction relatively with respect to another element may be referred to as being above, over or on the other element, and an element disposed in a −Z-axis direction relatively with respect to another element may be referred to as being below, under or beneath the other element. Also, an area of an element may denote a size, occupied by the element, of a plane parallel with a horizontal plane, and a width of an element may denote a length of the element in a direction perpendicular to a direction in which the element extends. In the drawings, for convenience of illustration, only some layers may be illustrated, and in order to illustrate a connection between a pattern of a wiring layer and a lower pattern, a via may be illustrated despite being disposed under the pattern of the wiring layer. Also, a pattern including a conductive material like the pattern of the wiring layer may be referred to as a conductive pattern, or may be simply referred to as a pattern.

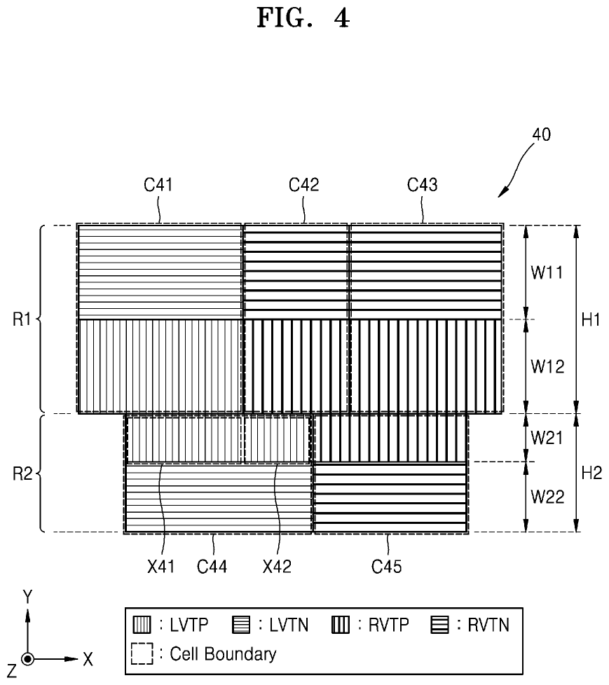

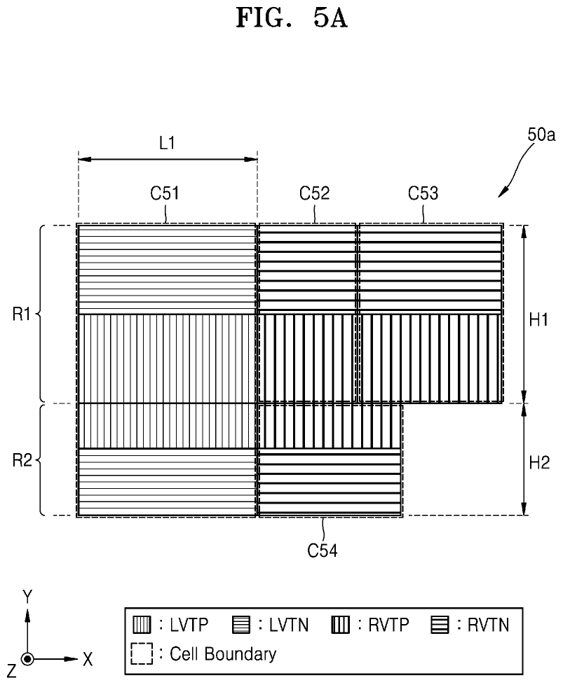

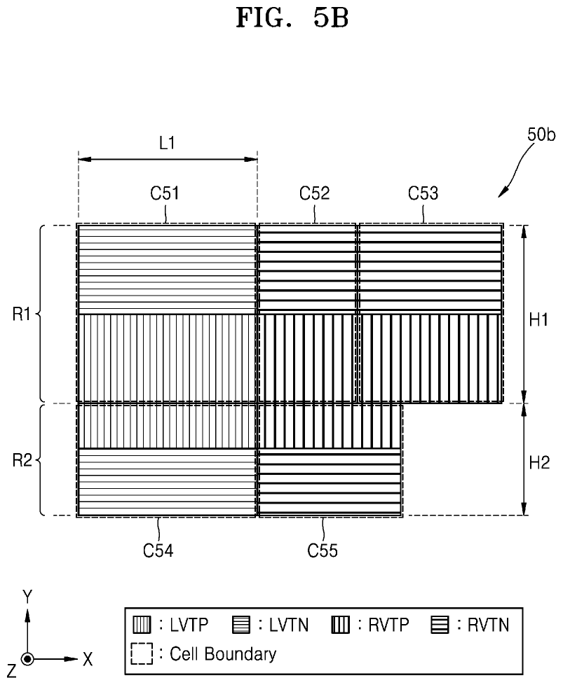

An integrated circuit may include a plurality of standard cells. A standard cell may be a unit of a layout included in an integrated circuit and may be simply referred to as a cell. A cell may include one or more transistors and may be designed to perform one or more predetermined functions. For example, the cell C10 may have a predetermined height (i.e., a length in the Y-axis direction) H1, and as described below with reference to FIG. 4 and the like, the cell C10 may be disposed in a row extending in the X-axis direction. A cell disposed in one row may be referred to as a single height cell, and as in a first cell C51 of FIG. 5A described below, cells continuously arranged in two or more rows may be referred to as a multiple height cell.

The cell C10 may include a PFET region and an NFET region extending in parallel in the X-axis direction, and a device isolation layer ISO may extend in the X-axis direction between the PFET region and the NFET region. As illustrated in FIG. 1, the PFET region may have a first width W1 in the Y-axis direction, and the NFET region may have a second width W2 in the X-axis direction. The first width W1 may be equal to or different from the second width W2. The cell C10 may include gate electrodes extending in the Y-axis direction with a contacted poly pitch (CPP) as their interval.

Referring to FIG. 2, a semiconductor device manufacturing process may form devices having different characteristics. For example, devices having different threshold voltages may be formed by a semiconductor device manufacturing process, and based on requirements, an integrated circuit may include devices having different threshold voltages. In some embodiments, as illustrated in FIG. 2, a device may have a threshold voltage corresponding to one of a high voltage threshold (HVT), a regular voltage threshold (RVT), a low voltage threshold (LVT), a super low voltage threshold (SLVT), and an ultra-low voltage threshold (ULVT). A device having a low threshold voltage may provide high performance (e.g., a high operation speed), and moreover, may have high power consumption. On the other hand, a device having a high threshold voltage may provide low power consumption, and moreover, may have low performance (e.g., a low operation speed). As described above, an integrated circuit including devices having different threshold voltages may be referred to as a multi-threshold integrated circuit, and based on the different-threshold devices, an optimized integrated circuit (i.e., an integrated circuit satisfying various requirements) may be provided. Herein, an FET will be mainly described as an example of a device and a threshold voltage will be mainly described as an example of a characteristic of a device, but embodiments are not limited thereto.

Devices having different threshold voltages may be respectively formed by different processes (or sub-processes). For example, as illustrated in FIG. 1, a first process 11 or a second process 12 may be used for forming devices of the 2-input NAND gate NAND2. The first process 11 may include a process for forming at least one PFET having a relatively lower threshold voltage, hereinafter referred to as “LVTP,” and a process for forming at least one NFET having a lower threshold voltage, hereinafter referred to as “LVTN,” and the LVTP and the LVTN may form a region having an area corresponding to a height H1 of the cell C10. Also, the second process 12 may include a process for forming at least one PFET having a relatively higher threshold voltage, hereinafter referred to as “RVTP,” and a process for forming at least one NFET having a higher threshold voltage, hereinafter referred to as “RVTN,” and the RVTP and the RVTN may form a region having an area corresponding to the height H1 of the cell C10. In some embodiments, a length of a region formed by each of the LVTP (or RVTP) and a region formed by the LVTN (or RVTN) in the Y-axis direction may depend on the first width W1 and the second width W2 described above. In some embodiments, the LVTP (or RVTP) and the LVTN (or RVTN) may respectively correspond to sub-processes of injecting different dopants.

First and second NFETs N1 and N2 and first and second PFETs P1 and P2 formed by the first process 11 may have higher threshold voltages, and first and second NFETs N1 and N2 and first and second PFETs P1 and P2 formed by the second process 12 may have lower threshold voltages. Devices of a cell C10 undergoing the first process 11 may have threshold voltages which are lower than those of devices of a cell C10 undergoing the second process 12, and thus, the cell C10 undergoing the first process 11 may have an operation speed and power consumption which are higher than those of the cell C10 undergoing the second process 12. In some embodiments, a cell C10 having a lower threshold voltage may include a critical path of an integrated circuit.

Due to a device having a reduced size, it may be limited that devices having different threshold voltages in an integrated circuit are freely formed. For example, as described below with reference to FIG. 4, a process may have a spatial limitation for forming a threshold voltage of a device, and thus, the free arrangement of devices having different threshold voltages may be limited. A dummy region may be added for resolving the spatial limitation, but may cause an increase in area of an integrated circuit. As described below with reference to the drawings, a spatial limitation may be easily resolved even without providing the dummy region, and thus, an integrated circuit including devices having different threshold voltages may satisfy various requirements and may provide high reliability. As a result, based on multi-threshold devices, an integrated circuit may provide optimal performance and efficiency.

FIGS. 3A to 3D are diagrams illustrating examples of a device according to embodiments. In detail, FIG. 3A illustrates a FinFET 30a, FIG. 3B illustrates a gate-all-around field effect transistor (GAAFET) (or nanowire transistor) 30b, FIG. 3C illustrates a multi-bridge channel field effect transistor (MBCFET) (or nanosheet transistor) 30c, and FIG. 3D illustrates a vertical field effect transistor (VFET) 30d. For convenience of illustration, FIGS. 3A to 3C illustrate an example where one of two source/drain regions is not shown, and FIG. 3D illustrates a cross-sectional view of the VFET 30d with respect to a plane which is parallel to a plane consisting of the Y axis and the Z axis and passes through a channel structure CH of the VFET 30d.

Referring to FIG. 3A, the FinFET 30a may be configured by a fin-shaped active pattern extending in an X-axis direction between shallow trench isolations (STIs) and a gate electrode G extending in a Y-axis direction. A source/drain region S/D may be formed at both sides of the gate electrode G, and thus, a source and a drain may be apart from each other in the X-axis direction. An insulation layer may be formed between the channel structure CH and the gate electrode G. In some embodiments, the FinFET 30a may be configured by the gate electrode G and a plurality of active patterns apart from one another in the Y-axis direction.

Referring to FIG. 3B, the GAAFET 30b may be configured by active patterns (i.e., nanowires), which are apart from one another in a Z-axis direction and extend in an X-axis direction, and a gate electrode G extending in a Y-axis direction. A source/drain region S/D may be formed at both sides of the gate electrode G, and thus, a source and a drain may be apart from each other in the X-axis direction. An insulation layer may be formed between the channel structure CH and the gate electrode G. The number of nanowires included in the GAAFET 30b is not limited to the illustration of FIG. 3B.

Referring to FIG. 3C, the MBCFET 30c may be configured by active patterns (i.e., nanosheets), which are apart from one another in a Z-axis direction and extend in an X-axis direction, and a gate electrode G extending in a Y-axis direction. A source/drain region S/D may be formed at both sides of the gate electrode G, and thus, a source and a drain may be apart from each other in the Y-axis direction. An insulation layer may be formed between the channel structure CH and the gate electrode G. The number of nanowires included in the MBCFET 30c is not limited to the illustration of FIG. 3C.

Referring to FIG. 3D, the VFET 30d may include a top source/drain region T_S/D and a bottom source/drain region B S/D, which are apart from each other in a Z-axis direction with a channel structure CH therebetween. The VFET 30d may include a gate electrode G which surrounds a perimeter of the channel structure CH between the top source/drain region T_S/D and the bottom source/drain region B S/D. An insulation layer may be formed between the channel structure CH and the gate electrode G.

As described above with reference to FIGS. 1 and 2, each of the FinFET 30a, the GAAFET 30b, the MBCFET 30c, and the VFET 30d may be formed by a semiconductor device manufacturing process to have one of different threshold voltages. Hereinafter, a cell including the FinFET 30a or the MBCFET 30c will be mainly described, but devices included in a cell are not limited to the illustrations of FIGS. 3A to 3D. For example, a cell may include a ForkFET having a structure where nanosheets for a P-type transistor and nanosheets for an N-type transistor may be divided by a dielectric wall, and thus, the P-type transistor is closer to the N-type transistor. Moreover, a cell may include a bipolar junction transistor as well as FETs such as a complementary FET (CFET), a negative capacitance FET (NCFET), and a carbon nanotube FET (CNT).

FIG. 4 is a diagram illustrating a layout of an integrated circuit 40 according to an embodiment. In detail, FIG. 4 illustrates processes corresponding to threshold voltages of devices in the integrated circuit 40. As described above with reference to FIG. 4, the devices included in the integrated circuit 40 may be formed to have different threshold voltages by using different processes. The integrated circuit 40 may include active patterns in an X-axis direction and gate electrodes in a Y-axis direction.

Referring to FIG. 4, the integrated circuit 40 may include first to third cells C41 to C43 arranged in a first row R1 extending in the X-axis direction, and fourth and fifth cells C44 and C45 arranged in a second row R2 extending in the X-axis direction. The integrated circuit 40 may include power rails to which supply voltages are respectively applied, so as to supply power to the cells. For example, a power rail through which a positive supply voltage VDD is supplied may extend in the X-axis direction along a boundary between the first row R1 and the second row R2, and power rails through which a negative supply voltage VSS (or a ground voltage) is supplied may respectively extend in the X-axis direction along other boundaries of the first row R1 and the second row R2. The first and fourth cells C41 and C44 may include at least one device formed by an LVTP and an LVTN for a lower threshold voltage, and the second, third, and fifth cells C42, C43, and C45 may include at least one device formed by an RVTP and an RVTN for a higher threshold voltage.

In some embodiments, rows in the integrated circuit 40 may have different heights. For example, a first height H1 of the first row R1 may be greater than a second height H2 of the second row R2, and thus, the first height H1 of each of the first to third cells C41 to C43 may also be greater than the second height H2 of each of the fourth and fifth cells C44 and C45 (H1>H2). Therefore, cells arranged in the first row R1 may have relatively higher performance, and cells arranged in the second row R2 may have a relatively smaller area. The integrated circuit 40 may include cells having different heights as well as devices having different threshold voltages, and thus, performance and efficiency (e.g., an area and power consumption) of the integrated circuit 40 may be maximized. In some embodiments, a pitch (i.e., CPP) of gate electrodes extending in the Y-axis direction in the first row R1 may be equal to that of gate electrodes extending in the Y-axis direction in the second row R2. In some embodiments, the first height H1 may be equal to the second height H2 (H1=H2).

In a case where the first to fifth cells C41 to C45 are arranged as illustrated in FIG. 4, it may not be easy to form PFETs of the fourth cell C44 of the second row R2 in a semiconductor device manufacturing process. As illustrated in FIG. 4, a region formed by the RVTP and a region formed by the RVTN may respectively have a first width W11 and a second width W12 in the first row R1 having the first height H1, and a region formed by the LVTP and a region formed by the LVTN may respectively have a third width W21 and a fourth width W22 in the second row R2 having the second height H2. As described above with reference to FIG. 1, in the second row R2, the third width W21 corresponding to the LVTP may differ from the fourth width W22 corresponding to the LVTN (e.g., W22>W21), and for example, the region of the LVTP and the region of the LVTN may be asymmetric with each other.

In some embodiments, due to the fourth width W22 which is relatively large, devices may be freely formed by the LVTN or the RVTN in the second row R2, and due to the third width W21 which is relatively small, it may be limited that the devices are freely formed by the LVTN or the RVTN in the second row R2. For example, at least one device (e.g., PFET) included in a first region X41 in the fourth cell C44 may be easily formed due to the LVTP for the first cell C41 adjacent to the fourth cell C44, and it may not be easy to form at least one device (e.g., PFET) included in a second region X42 in the fourth cell C44. A region of the RVTP, where it is not easy to form at least one device like the second region X42, may also be formed or exist. In order to avoid formation of the second region X42 of FIG. 4, a dummy region (e.g., a filler cell) may be inserted, and thus, an area of an integrated circuit may increase, and optimization by devices having different threshold voltages and/or rows having different heights may be limited. Hereinafter, embodiments for avoiding formation of the second region X42 of FIG. 4 will be described with reference to the drawings.

FIGS. 5A and 5B are diagrams illustrating examples of layouts of integrated circuits 50a and 50b according to embodiments. In detail, FIGS. 5A and 5B illustrate processes corresponding to threshold voltages of devices in the integrated circuits 50a and 50b. As described above with reference to FIG. 4, a power rail through which a positive supply voltage VDD is supplied may extend in an X-axis direction along a boundary between a first row R1 and a second row R2. Hereinafter, in describing FIGS. 5A and 5B, descriptions which are the same as or similar to the descriptions of FIG. 4 are omitted.

Referring to FIG. 5A, the integrated circuit 50a may include first to fourth cells C51 to C54. The first cell C51 may include at least one device formed by an LVTP and an LVTN, and the second to fourth cells C52 to C54 may include at least one device formed by an RVTP and an RVTN. The first cell CM may be a multi-height cell and may be continuously arranged in a first row R1 and a second row R2. In some embodiments, the first cell C51 may include circuits which respectively perform independent functions, and the circuits may be respectively formed in different rows. For example, the first cell C51 may include at least one device configured to perform a first function in the first row R1, and at least one device configured to perform a second function, which is independent of the first function, in the second row R2.

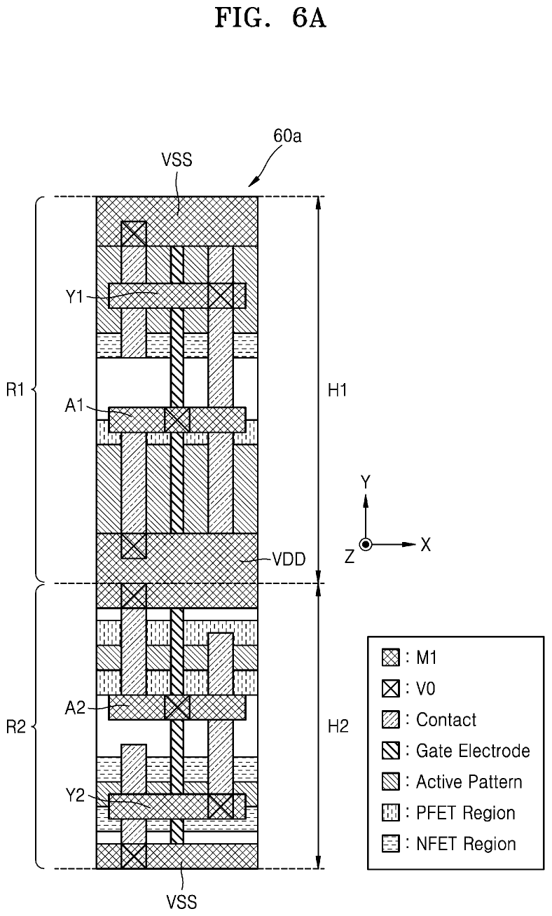

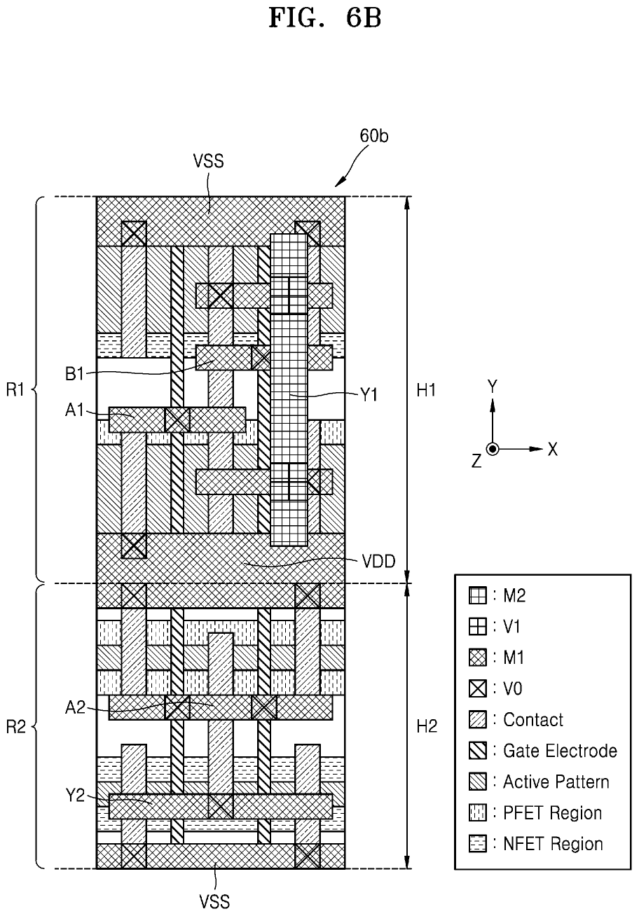

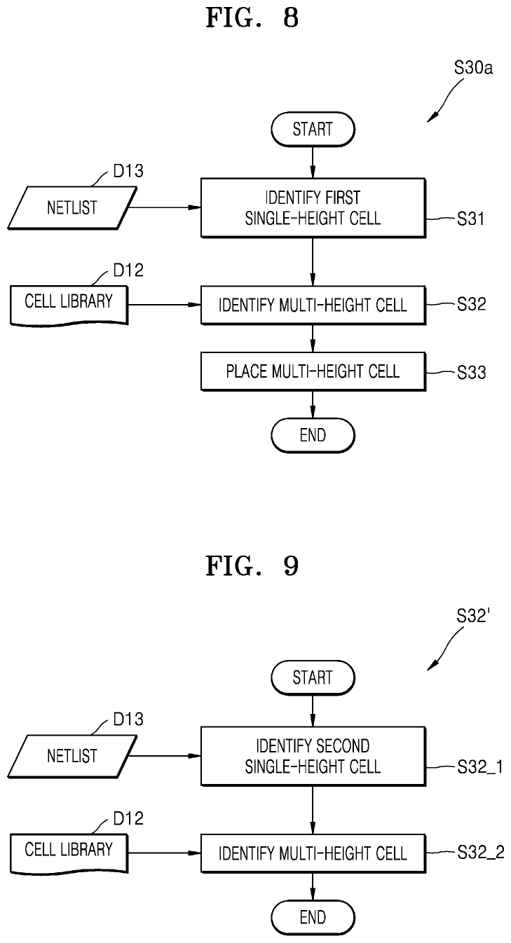

The first cell C51 may have a certain length L1 in an X-axis direction, and may abut the second and fourth cells C52 and C54 at a boundary extending in a Y-axis direction. When the fourth cell C44 of FIG. 4 includes at least one device configured to perform the second function, as described below with reference to FIG. 8, the fourth cell C44 of FIG. 4 may be replaced with at least a portion of the first cell C51 of FIG. 5A. Accordingly, the second region X42 of FIG. 4 may not be formed, and at least one device configured to perform the second function may be easily formed. Also, a region corresponding to the first row R1 of the first cell C51 may include at least one device configured to perform the first function instead of being limited by a dummy region, and thus, an increase in an area of the integrated circuit 50a may be prevented. Embodiments of the first cell C51 will be described below with reference to FIGS. 6A and 6B.

Referring to FIG. 5B, the integrated circuit 50b may include first to fifth cells C51 to C55. The first and fourth cells CM and C54 may include at least one device formed by an LVTP and an LVTN, and the second, third, and fifth cells C52, C53, and C55 may include at least one device formed by an RVTP and an RVTN. The first cell CM may include at least one device configured to perform a first function, and the fourth cell C54 may include at least one device configured to perform a second function.

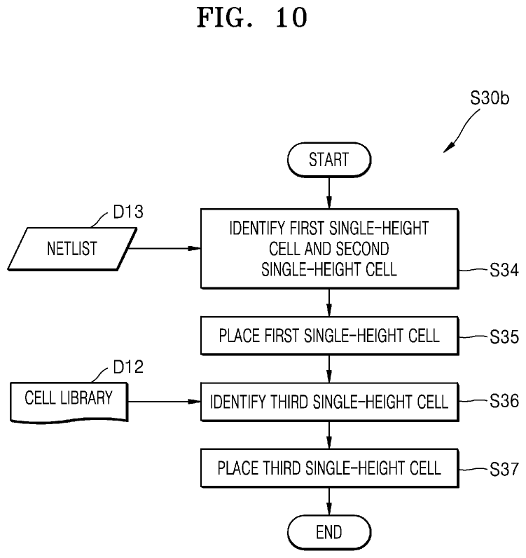

The first cell CM and the fourth cell C54 may have the same length L1 in an X-axis direction and may be arranged in a Y-axis direction. Therefore, a boundary between the first and second cells CM and C52 and a boundary between the fourth and fifth cells C54 and C55 may be arranged in the Y-axis direction. As in the fourth cell C44 of FIG. 4, in a case where the fourth cell C54 of FIG. 5B is disposed in a second row R2, as described below with reference to FIG. 10, the first cell CM having the same length (i.e., L1) as that of the fourth cell C54 in the X-axis direction may be aligned with the fourth cell C54 in a first row R1. Accordingly, the second region X42 of FIG. 4 may not be formed or exist, and at least one device configured to perform the second function may be easily formed. Also, based on the first cell C51, a dummy region may not be necessary in the first row R1, and thus, an increase in an area of the integrated circuit 50b may be prevented. Examples of the first and fourth cells C51 and C54 will be described below with reference to FIGS. 6A and 6B.

FIGS. 6A and 6B are diagrams illustrating examples of layouts of integrated circuits 60a and 60b according to embodiments. In detail, FIGS. 6A and 6B illustrate examples of the first cell CM of FIG. 5A and the first and fourth cells CM and C54 of FIG. 5B. As described above with reference to FIGS. 5A and 5B, due to a multi-height cell or single-height cells aligned in a Y-axis direction, the second region X42 of FIG. 4 may not be formed or exist, and devices having different threshold voltages may be easily formed. The first cell CM of FIG. 5A and the first and fourth cells CM and C54 of FIG. 5B are not limited to examples of FIGS. 6A and 6B. In FIGS. 6A and 6B, a first height H1 of a first row R1 may be greater than a second height H2 of a second row R2 (H1>H2). Hereinafter, in describing FIGS. 6A and 6B, repeated descriptions are omitted.

Referring to FIG. 6A, the integrated circuit 60a may include at least one cell which is independent from each other and provide the same functions in a first row R1 and a second row R2. For example, as illustrated in FIG. 6A, the integrated circuit 60a may include at least one device configuring a first inverter in the first row R1 and at least one device configuring a second inverter in the second row R2. The first inverter may include an NFET and a PFET which are MBCFETs including an active pattern (i.e., a bridge) having a relatively wide width and are serially connected with each other between a positive supply voltage VDD and a negative supply voltage VSS, and the second inverter may include an NFET and a PFET which are MBCFETs including a bridge having a relatively narrow width and are serially connected with each other between the positive supply voltage VDD and the negative supply voltage VSS.

At least one device in the first row R1 and the second row R2 may have the same threshold voltage by using the same process, and thus, may be easily formed without spatial limitations. As illustrated in FIG. 6A, a pattern of an M1 layer supplied with the positive supply voltage VDD may extend in the X-axis direction along a boundary between the first row R1 and the second row R2, and patterns of the M1 layer supplied with the negative supply voltage VSS may respectively extend in the X-axis direction along other boundaries of the first row R1 and the second row R2.

The first inverter may include a first input pin A1 and a first output pin Y1 as patterns of the M1 layer, and the second inverter may include a second input pin A2 and a second output pin Y2 as patterns of the M1 layer. In some embodiments, as described above with reference to FIG. 5A, the first inverter and the second inverter may be included in one multi-height cell, and the pattern of the M1 layer through which the positive supply voltage VDD is supplied may pass through a multi-height cell. In some embodiments, as described above with reference to FIG. 5B, the first inverter and the second inverter may be respectively included in two single-height cells, and the pattern of the M1 layer through which the positive supply voltage VDD is supplied may be shared by two single-height cells.

Referring to FIG. 6B, the integrated circuit 60b may include cells which are independent from each other and provide different functions in a first row R1 and a second row R2. For example, as illustrated in FIG. 6B, the integrated circuit 60b may include at least one device configuring a 2-input NOR gate in the first row R1 and at least one device configuring an inverter in the second row R2. Devices of the first row R1 and the second row R2 may have the same threshold voltage by being formed using the same process, and thus, may be easily formed without spatial limitations. As illustrated in FIG. 6B, a pattern of an M1 layer through which a positive supply voltage VDD is supplied may extend in an X-axis direction along a boundary between the first row R1 and the second row R2, and patterns of the M1 layer through which a negative supply voltage VSS is supplied with may respectively extend in the X-axis direction along another boundaries of the first row R1 and the second row R2.

The 2-input NOR gate may include two first input pins A1 and B1 as patterns of the M1 layer and a first output pin Y1 as a pattern of an M2 layer, and the inverter may include a second input pin A2 and a second output pin Y2 as patterns of the M1 layer. The 2-input NOR gate may include two PFETs serially connected between the positive supply voltage VDD and the first output pin Y1 and two NFETs connected in parallel between the first output pin Y1 and the negative supply voltage VSS. The inverter may include a PFET and an NFET connected serially between the positive supply voltage VDD and the negative supply voltage VSS.

In some embodiments, as described above with reference to FIG. 5A, the 2-input NOR gate and the inverter may be included in one multi-height cell, and the pattern of the M1 layer through which the positive supply voltage VDD is supplied with may pass through a multi-height cell. In some embodiments, as described above with reference to FIG. 5B, the 2-input NOR gate and the inverter may be respectively included in two single-height cells, and the pattern of the M1 layer through which the positive supply voltage VDD is supplied may be shared by two single-height cells.

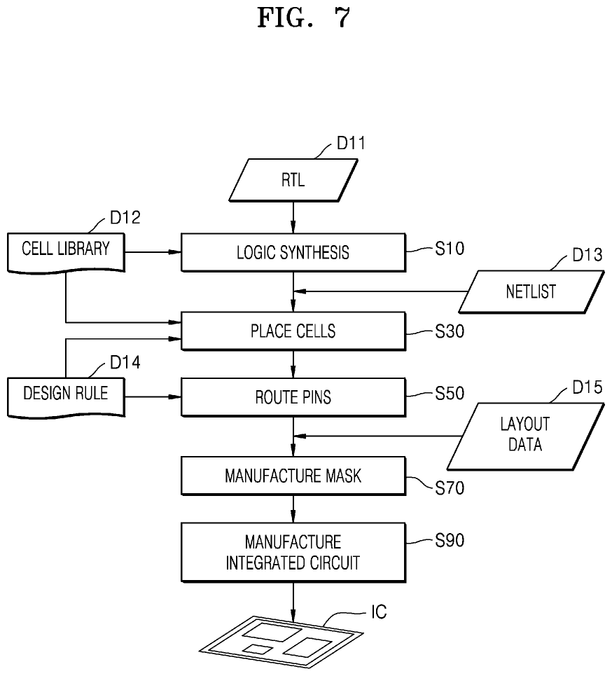

FIG. 7 is a flowchart illustrating a method of designing an integrated circuit IC, according to an embodiment. In detail, the flowchart of FIG. 7 illustrates an example of a method of designing the integrated circuit IC including cells. The method of designing the integrated circuit IC illustrated in FIG. 7 may be referred to as a method of manufacturing the integrated circuit IC. As illustrated in FIG. 7, the method of designing the integrated circuit IC may include a plurality of operations S10, S30, S50, S70, and S90.

A cell library (or a standard cell library) D12 may include information (e.g., information about functions, characteristic, and layouts) about cells. In some embodiments, the cell library D12 may define cells respectively including devices having different characteristics. For example, the cell library D12 may define cells including devices having different threshold voltages, respectively, and may define two or more cells which provide the same function or respectively include devices having different threshold voltages. The cell library D12 may define a multi-height cell as well as a single-height cell.

A design rule D14 may include requirements which a layout of the integrated circuit IC has to conform. For example, the design rule D14 may include requirements, such as a space between patterns, a minimum width of a pattern, and a routing direction of a wiring layer, in a layer. In some embodiments, the design rule D14 may define spatial limitations needed for forming a threshold voltage to filter the second region X42 of FIG. 4.

In operation S10, a logic synthesis operation of generating a netlist D13 from register transfer level (RTL) data D11 may be performed. For example, a semiconductor design tool (e.g., a logic synthesis tool) may perform logic synthesis with reference to the cell library D12 from the RTL data D11 written in hardware description language (HDL) such as Verilog and very high-speed integrated circuit (VHSIC) hardware description language (VHDL), and thus, may generate the netlist D13 including a bitstream or a netlist. The netlist D13 may correspond to an input of place and routing described below.

In operation S30, cells may be placed. For example, a semiconductor design tool (e.g., a place-and-route (P&R) tool) may place cells used in the netlist D13 with reference to the cell library D12. In some embodiments, the semiconductor design tool may select a cell including devices having a certain threshold voltage from the cell library D12 and may place the selected cell. In some embodiments, the semiconductor design tool may place cells so that a region, such as the second region X42 of FIG. 4, does not occur. For example, the semiconductor design tool may place at least one first cell including a first threshold voltage device having a first threshold voltage and at least one second cell including a second threshold voltage device having a second threshold voltage to be abutted at a boundary extending in the Y-axis direction in a first row and a second row adjacent to each other. Examples of operation S30 will be described below with reference to FIGS. 8 and 10.

In operation S50, pins of cells may be routed. For example, the semiconductor design tool may generate interconnections which electrically connect output pins of placed cells with input pins thereof and may generate layout data D15 which defines the placed cells and the generated interconnections. Each of the interconnections may include a via of a via layer and/or a pattern of a wiring layer. The layout data D15 may have, for example, a format, such as GDSII, and may include geometric information about the cells and the interconnections. The semiconductor design tool may refer to the design rule D14 while routing pins of cells. The layout data D15 may correspond to an output of routing and placement. Operation S50 may be referred to as a method of designing an integrated circuit, or operations S30 and S50 may be collectively referred to as a method of designing an integrated circuit.

In operation S70, an operation of fabricating a mask may be performed. For example, optical proximity correction (OPC) for correcting distortion, such as infraction caused by a characteristic of light in photolithography, may be applied to the layout data D15. Based on data to which OPC is applied, patterns of a mask may be defined for forming patterns disposed in a plurality of layers, and at least one mask (or photomask) for forming patterns of each of the plurality of layers may be fabricated. In some embodiments, a layout of the integrated circuit IC may be restrictively modified in operation S70, and an operation of restrictively modifying the integrated circuit IC in operation S70 may be post-processing for optimizing a structure of the integrated circuit IC and may be referred to as design polishing.

In operation S90, an operation of manufacturing the integrated circuit IC may be performed. For example, the integrated circuit IC may be manufactured by patterning a plurality of layers with at least one mask which is fabricated in operation S70. Front-end-of-line (FEOL) may include, for example, an operation of planarizing and cleaning a wafer, an operation of forming a trench, an operation of forming a well, an operation of forming a gate electrode, and an operation of forming a source and a drain, and individual devices (e.g., a transistor, a capacitor, a resistor, etc.) may be formed in a substrate by FEOL. Also, back-end-of-line (BEOL) may include, for example, a silicidation of a source and drain region, adding a dielectric, a planarization, forming a hole, adding a metal layer, forming a via, and forming a passivation layer, and the individual devices (e.g., the transistor, the capacitor, the resistor, etc.) may be connected with one another by BEOL. In some embodiments, middle-of-line (MOL) may be performed between FEOL and BEOL, and contact structures may be formed on the individual devices. Subsequently, the integrated circuit IC may be packaged into a semiconductor package and may be used as parts of various applications.

FIG. 8 is a flowchart illustrating a method of designing an integrated circuit, according to an embodiment. In detail, the flowchart of FIG. 8 illustrates an example of operation S30 of FIG. 7. As described above with reference to FIG. 7, cells may be placed in operation S30a of FIG. 8. As illustrated in FIG. 8, operation S30a may include a plurality of operations S31 to S33. Hereinafter, FIG. 8 will be described with reference to FIGS. 4 and 5A.

Referring to FIG. 8, a first single-height cell may be identified in operation S31. In some embodiments, the semiconductor design tool may identify a first single-height cell including a device having a first threshold voltage (i.e., a first threshold voltage device) from the netlist D13 from among cells included in an integrated circuit. For example, the semiconductor design tool may identify the fourth cell C44, providing a second function, from the netlist D13. In some embodiments, the first single-height cell may be disposed adjacent to a single-height cell or a multi-height cell, including a device having a second threshold voltage (i.e., a second threshold voltage device) which differs from the first threshold voltage, in an X-axis direction.

In operation S32, the multi-height cell may be identified. In some embodiments, the semiconductor design tool may identify a multi-height cell including the first threshold voltage device from the cell library D12, based on the first single-height cell which is identified in operation S31. For example, the semiconductor design tool may identify a second function of the fourth cell C44 of FIG. 4 and may identify the first cell C51 of FIG. 5A, providing the identified second function of the fourth cell C44 in a second row R2 having a second height H2, from the cell library D12. In some embodiments, the identified multi-height cell may include the same structure as that of the first single-height cell, which is identified in operation S31, in the second row R2. The identified multi-height cell may provide a first function, which is independent of the second function, in the first row R1, and thus, an undesired dummy region may be omitted. An example of operation S32 will be described below with reference to FIG. 9.

In operation S33, the multi-height cell may be placed. In some embodiments, the semiconductor design tool may place the multi-height cell, which is identified in operation S32, in the first row R1 and the second row R2. For example, the semiconductor design tool may place the first cell C51 of FIG. 5A in the first row R1 and the second row R2, and thus, a region, such as the second region X42 of FIG. 4, may not occur.

FIG. 9 is a flowchart illustrating a method of designing an integrated circuit, according to an embodiment. In detail, the flowchart of FIG. 9 illustrates an example of operation S32 of FIG. 8. As described above with reference to FIG. 8, a multi-height cell may be identified in operation S32′ of FIG. 9. As illustrated in FIG. 9, operation S32′ may include operation S32_1 and operation S32_2. Hereinafter, FIG. 9 will be described with reference to FIGS. 5A and 8.

Referring to FIG. 9, a second single-height cell may be identified in operation S32_1. In some embodiments, the semiconductor design tool may identify a second single-height cell including a device having a first threshold voltage (i.e., a first threshold voltage device) from the netlist D13 from among cells included in an integrated circuit.

In operation S32_2, the multi-height cell may be identified. In some embodiments, the semiconductor design tool may identify a multi-height cell including the first threshold voltage device from the netlist D12, based on the first single-height cell identified in operation S31 of FIG. 8 and the second single-height cell identified in operation S32_1. For example, the semiconductor design tool may identify a second function of the first single-height cell identified in operation S31 of FIG. 8 and a first function of the second single-height cell identified in operation S32_1. The semiconductor design tool may identify a multi-height cell (e.g., the first cell CM of FIG. 5A), providing the identified first function in the first row R1 and providing the identified second function in the second row R2, from the cell library D12. To this end, the cell library D12 may define a plurality of multi-height cells which provide the second function in the row R2 and respectively provide a plurality of functions in the first row R1. As a result, the first single-height cell and the second single-height cell may be replaced by one multi-height cell, and thus, an undesired dummy region may be removed.

FIG. 10 is a flowchart illustrating a method of designing an integrated circuit, according to an embodiment. In detail, the flowchart of FIG. 10 illustrates an example of operation S30 of FIG. 7. As described above with reference to FIG. 7, cells may be placed in operation S30b of FIG. 10. As illustrated in FIG. 10, operation S30b may include a plurality of operations S34 to S37. Hereinafter, FIG. 10 will be described with reference to FIGS. 4 and 5B.

Referring to FIG. 10, in operation S34, a first single-height cell and a second single-height cell may be identified. In some embodiments, the semiconductor design tool may identify a first single-height cell and a second single-height cell each including a device having a first threshold voltage (i.e., a first threshold voltage device) from among cells included in an integrated circuit. For example, the semiconductor design tool may identify the first cell C41 of FIG. 4 providing a first function and the fourth cell C44 of FIG. 4 providing a second function. In some embodiments, the first single-height cell and the second single-height cell may be cells which are disposed adjacent to a single-height cell or a multi-height cell, including a device having a second threshold voltage (i.e., a second threshold voltage device) which differs from the first threshold voltage, in an X-axis direction.

In operation S35, the first single-height cell may be placed. In some embodiments, the semiconductor design tool may place the first single-height cell from among single-height cells which are identified in operation S34. For example, the semiconductor design tool may place the fourth cell C44 in the second row R2.

In operation S36, a third single-height cell may be identified. In some embodiments, the semiconductor design tool may identify the third single-height cell, which provides the same function as that of the second single-height cell identified in operation S34 and has the same length as that of the first single-height cell placed in operation S35 in the X-axis direction, from the cell library D12. For example, the semiconductor design tool may identify the first cell CM, which has the same length L1 as that of the fourth cell C54 of FIG. 5B in the X-axis direction and provides the second function, from the cell library D12. To this end, the cell library D12 may define a plurality of single-height cells which provide the same function and respectively have various lengths in the X-axis direction.

In operation S37, the third single-height cell may be placed. In some embodiments, the semiconductor design tool may place the third single-height cell, which is identified in operation S36, to be aligned with the first single-height cell which is placed in operation S35. For example, the semiconductor design tool may place the first cell C51 of FIG. 5B in the first row R1 to be aligned with the fourth cell C54. As a result, the second single-height cell may be replaced by the third single-height cell, and thus, an undesired dummy region may be removed.

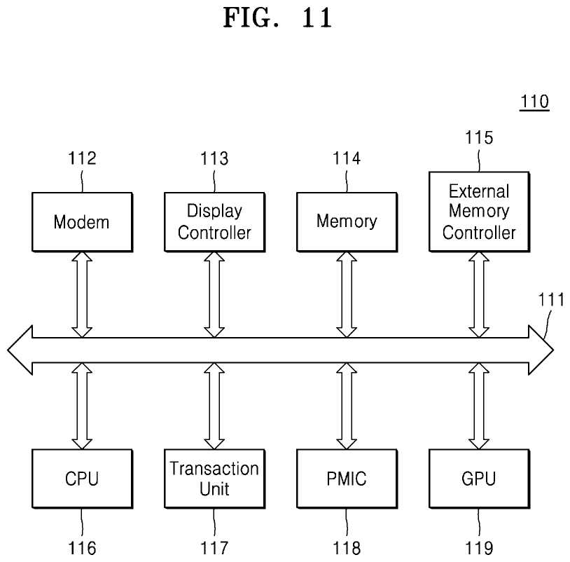

FIG. 11 is a block diagram illustrating a system on chip (SoC) 110 according to an embodiment. The SoC 110 may be a semiconductor device and may include an integrated circuit according to an embodiment. In the SoC 110, like intellectual property (IP) performing various functions, a plurality of blocks may be implemented in one chip. According to embodiments, the SoC 110 may include devices having different threshold voltages, and thus, may have optimal performance and efficiency. Referring to FIG. 11, the SoC 110 may include a modem 112, a display controller 113, a memory 114, an external memory controller 115, a central processing unit (CPU) 116, a transaction unit 117, a power management integrated circuit (PMIC) 118, and a graphics processing unit (GPU) 119, and function blocks of the SoC 110 may communicate with one another through a system bus 111.

The CPU 116 for controlling an operation of the SoC 110 in an uppermost layer may control operations of the other function blocks (112 to 119). The modem 112 may demodulate a signal received from the outside of the SoC 110, or may modulate a signal generated in the SoC 110 and may transmit the modulated signal to the outside. The external memory controller 115 may control an operation of transferring or receiving data from or to an external memory device connected to the SoC 110. For example, a program and/or data stored in the external memory device may be supplied to the CPU 116 or the GPU 119, based on control by the external memory controller 115.

The GPU 119 may execute program instructions associated with graphics processing. The GPU 119 may receive graphics data through the external memory controller 115 and may transmit graphics data, obtained through processing by the GPU 119, to the outside of the SoC 110 through the external memory controller 115. The transaction unit 117 may monitor data transactions of the function blocks. The PMIC 118 may control power supplied to each of the function blocks, based on control by the transaction unit 117. The display controller 113 may control a display (or a display device) outside the SoC 110, and thus, may transmit data, generated in the SoC 110, to the display.

The memory 114 may store data and/or instructions and may be accessed by the other elements of the SoC 110 through the system bus 111. The memory 114 may include a non-volatile memory, such as electrically erasable programmable read-only memory (EEPROM) or flash memory, or may include a volatile memory, such as dynamic random access memory (DRAM) or static random access memory (SRAM).

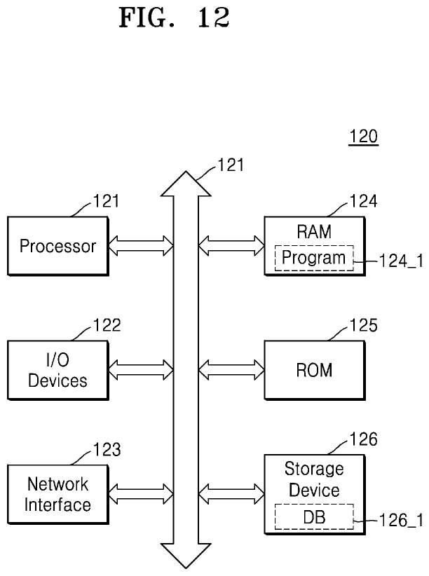

FIG. 12 is a block diagram illustrating a computing system 120 including a memory storing a program, according to an embodiment. In a method of designing an integrated circuit according to embodiments, for example, at least some of the operations of the flowcharts described above may be performed by the computing system (or a computer) 120.

The computing system 120 may include a stationary computing system, such as a desktop computer, a workstation, or a server, or may include a portable computing system, such as a laptop computer. As illustrated in FIG. 12, the computing system 120 may include a processor 121, input/output (I/O) devices 122, a network interface 123, random access memory (RAM) 124, read only memory (ROM) 125, and a storage device 126. The processor 121, the I/O devices 122, the network interface 123, the RAM 124, the ROM 125, and the storage device 126 may be connected to a bus 127 and may communicate with one another through the bus 127.

The processor 121 may be referred to as a processing unit, and for example, may include at least one core for executing an arbitrary instruction set (e.g., Intel Architecture-32 (IA-32), 64-bit extension IA-32, x86-64, PowerPC, Sparc, MIPS, ARM, IA-64, etc.) like a micro-processor, an application processor (AP), a digital signal processor (DSP), and a GPU. For example, the processor 121 may access a memory (i.e., the RAM 124 or the ROM 125) through the bus 127 and may execute instructions stored in the RAM 124 or the ROM 125.

The RAM 124 may store a program 124_1 for the method of designing an integrated circuit according to an embodiment or at least a portion thereof, and the program 124_1 may allow the processor 121 to perform the method of designing an integrated circuit (e.g., at least some of the operations included in the methods of FIGS. 7 to 10). That is, the program 124_1 may include a plurality of instructions executable by the processor 121, and the plurality of instructions included in the program 124_1 may allow the processor 121 to perform, for example, at least some of the operations included in the flowcharts described above.

The storage device 126 may denote a non-transitory storage medium where stored data is not deleted even when power supplied to the computing system 120 is cut off. For example, the storage device 126 may include a non-volatile memory device, or may include a storage medium, such as magnetic tape, an optical disk, or a magnetic disk. Also, the storage device 126 may be detachably attached on the computing system 120. The storage device 126 may store the program 124_1 according to an embodiment, and the program 124_1 or at least a portion thereof may be unloaded from the storage device 126 before the program 124_1 is executed by the processor 121. In some embodiments, the storage device 126 may store a file written in a program language, and the program 124_1 generated by a compiler or at least a portion thereof may be loaded from a file into the RAM 124. Also, as illustrated in FIG. 12, the storage device 126 may store a database 126_1, and the database 126_1 may include information (e.g., D12 and D14 of FIG. 7) needed for designing an integrated circuit and/or information (e.g., D13 and D15 of FIG. 7) about an integrated circuit.

The storage device 126 may store data, which is to be processed by the processor 121, or data obtained through processing by the processor 121. That is, the processor 121 may process data stored in the storage device 126 to generate data, based on the program 124_1, and may store the generated data in the storage device 126. For example, the storage device 126 may store the RTL data D11, the netlist D13, and/or the layout data D15 of FIG. 7.

The I/O devices 122 may include an input device, such as a keyboard or a pointing device, and may include an output device, such as a display device or a printer. For example, a user may trigger the execution of the program 124_1 by the processor 121, input the RTL data D11 and/or the netlist D13 of FIG. 7, or check the layout data D15 of FIG. 7, through the I/O devices 122.

The network interface 123 may provide access to a network outside the computing system 120. For example, the network may include a plurality of computing systems and communication links, and the communication links may include wired links, optical links, wireless links, or other arbitrary types of links.

Hereinabove, embodiments have been described in the drawings and the specification. Embodiments have been described by using the terms described herein, but this has been merely used for describing the disclosure and has not been used for limiting a meaning or limiting the scope of the disclosure defined in the following claims. Therefore, it may be understood by those of ordinary skill in the art that various modifications and other equivalent embodiments may be implemented from the disclosure.

While the disclosure has been particularly shown and described with reference to embodiments thereof, it will be understood that various changes in form and details may be made therein without departing from the spirit and scope of the following claims.

What is claimed is:

1. An integrated circuit comprising:
a first cell disposed in a first row and a second row, and comprising a plurality of first threshold voltage devices, the first row and the second row being adjacent to each other and extending in a first direction; and
at least one second cell disposed adjacent to the first cell in at least one of the first row and the second row and comprising at least one second threshold voltage device,
wherein the plurality of first threshold voltage devices comprise:
at least one first device configured to perform a first function in the first row; and
at least one second device configured to perform a second function, which is independent of the first function, in the second row.

2. The integrated circuit of claim 1, wherein the first cell has a certain length in the first direction.

3. The integrated circuit of claim 1, wherein the first row has a first height in a second direction perpendicular to the first direction, and
wherein the second row has a second height, which is smaller than the first height, in the second direction.

4. The integrated circuit of claim 3, wherein the at least one second device comprise a device of a first-polarity type disposed in a first region of the second row and a device of a second-polarity type disposed in a second region of the second row,
wherein the first region has a first width in the second direction perpendicular to the first direction, and
wherein the second region has a second width smaller than the first width in the second direction.

5. The integrated circuit of claim 1, wherein the first cell comprises at least one first gate electrode extending in a second direction perpendicular to the first direction,
wherein the at least one second cell comprises at least one second gate electrode extending in the second direction, and
wherein a pitch of the at least one first gate electrode is the same as a pitch of the at least one second gate electrode.

6. The integrated circuit of claim 1, wherein the at least one first device is configured to generate at least one first output signal from at least one first input signal, based on the first function, and
wherein the at least one second device is configured to generate at least one second output signal from at least one second input signal, based on the second function.

7. The integrated circuit of claim 1, wherein the first cell further comprises a conductive pattern extending in the first direction along a boundary between the first row and the second row and configured to receive a supply voltage for supplying power to the plurality of first threshold voltage devices.

8. The integrated circuit of claim 1, wherein each of the plurality of first threshold voltage devices and the at least one second threshold voltage device comprises at least one of a fin field-effect transistor (FinFET), a gate-all-around field-effect transistor (GAAFET), a multi-bridge channel field-effect transistor (MBCFET), and a vertical field-effect transistor (VFET).

9. An integrated circuit comprising:
a first cell disposed in a first row extending in a first direction and comprising a plurality of first threshold voltage devices;
a second cell disposed in a second row and comprising a plurality of first threshold voltage devices, the second row being adjacent to the first row and extending in the first direction; and
at least one third cell disposed adjacent to the first cell and the second cell in at least one of the first row and the second row and comprising at least one second threshold voltage device,
wherein the first cell and the second cell are aligned in a second direction perpendicular to the first direction and have the same length in the first direction.

10. The integrated circuit of claim 9, wherein each of the first row and the first cell has a first height in the second direction, and
wherein each of the second row and the second cell has a second height smaller than the first height in the second direction.

11. The integrated circuit of claim 10, wherein the second cell comprises:
at least one first threshold voltage device of a first-polarity type disposed in a first region of the second cell; and
at least one first threshold voltage device of a second-polarity type disposed in a second region of the second cell,
wherein the first region has a first width in the second direction, and
wherein the second region has a second width smaller than the first width in the second direction.

12. The integrated circuit of claim 9, wherein the first cell comprises at least one first gate electrode extending in the second direction,
wherein the second cell comprises at least one second gate electrode extending in the second direction, and
wherein the at least one first gate electrode and the at least one second gate electrode are aligned in the second direction.

13. The integrated circuit of claim 9, further comprising:
a plurality of conductive patterns respectively connected to at least one input pin and at least one output pin of the first cell; and
a plurality of conductive patterns respectively connected to at least one input pin and at least one output pin of the second cell.

14. The integrated circuit of claim 9, wherein the first cell and the second cell share a conductive pattern extending in the first direction along a boundary between the first row and the second row and configured to receive a supply voltage for supplying power to the first cell and the second cell in common.

15. The integrated circuit of claim 9, wherein each of the plurality of first threshold voltage devices and the at least one second threshold voltage device comprises at least one of a fin field-effect transistor (FinFET), a gate-all-around field-effect transistor (GAAFET), a multi-bridge channel field-effect transistor (MBCFET), and a vertical field-effect transistor (VFET).

16. A method of designing an integrated circuit comprising a plurality of cells, the method comprising:
obtaining a netlist defining the plurality of cells; and
placing the plurality of cells in a plurality of rows extending in a first direction, based on the netlist,
wherein the placing the plurality of cells comprises placing at least one first cell comprising a first threshold voltage device and at least one second cell comprising a second threshold voltage device to abut each other at a boundary extending in a second direction perpendicular to the first direction.

17. The method of claim 16, wherein the placing the at least one first cell and the at least one second cell comprises:
identifying a first single-height cell comprising a first threshold voltage device, based on the netlist;
identifying a multi-height cell from a cell library, based on the first single-height cell; and
placing the multi-height cell in a first row and a second row adjacent to each other, and
wherein the multi-height cell comprises a structure of the first single-height cell.

18. The method of claim 17, wherein the identifying the multi-height cell comprises:
identifying a second single-height cell comprising a first threshold voltage device, based on the netlist; and
identifying the multi-height cell from the cell library, based on the first single-height cell and the second single-height cell.

19. The method of claim 16, wherein the placing the at least one first cell and the at least one second cell comprises:
identifying a first single-height cell and a second single-height cell each comprising a first threshold voltage device, based on the netlist;
placing the first single-height cell in a first row;
identifying a third single-height cell having the same length as a length of the first single-height cell in the second direction from a cell library, based on the second single-height cell; and
placing the third single-height cell in a second row to be adjacent to the first single-height cell.

20. The method of claim 16, further comprising:
generating layout data defining the plurality of cells;
fabricating at least one mask, based on the layout data; and
manufacturing the integrated circuit, based on the at least one mask.
